(19) United States
(12) Patent Application Publication
(10) Pub. No.: US 2026/0101730 A1
(43) Pub. Date: Apr. 9, 2026

(54) DAMAGE-LESS HYDROGEN TREATMENT FOR MOLYBDENUM OXIDE REDUCTION

(71) Applicant: Applied Materials, Inc., Santa Clara, CA (US)

(72) Inventors: Ruinan ZHOU, Santa Clara, CA (US); Jiajie CEN, Santa Clara, CA (US); Hsien-Lung YANG, Santa Clara, CA (US); Shashank S. SHARMA, Sunnyvale, CA (US); Archana KUMAR, Mountain View, CA (US)

(21) Appl. No.: 18/910,618

(22) Filed: Oct. 9, 2024

(51) Int. Cl. H01L 21/321

(52) U.S. Cl. CPC H10P 95/00

(57) ABSTRACT

In some embodiments, a method includes positioning a semiconductor structure within a processing chamber. The semiconductor structure includes a first layer disposed over a substrate surface. The semiconductor structure further includes a second layer disposed over the first layer. The second layer has a hardmask layer. The semiconductor structure further includes one or more second dielectric layers disposed over the second layer. The one or more second dielectric layers have a gap formed over a portion of the second layer. The semiconductor structure further includes a metal material disposed within the gap formed over the second layer. The metal material has a molybdenum oxide (MoOₓ) layer. The method further includes flowing a process gas into the processing chamber, and performing a redox operation on a portion of the semiconductor structure to reduce the MoOₓ to molybdenum (Mo). The redox operation includes applying a microwave energy to the process gas.

### BACKGROUND

### Field

Embodiments of the present disclosure generally relate to non-plasma methods of processing a substrate. More specifically, the methods disclosure herein incorporate a high pressure hydrogen soak to reduce a molybdenum oxide (MoOₓ) content in a semiconductor structure to molybdenum (metal).

### Description of the Related Art

Molybdenum (Mo) materials/doping have not been used in back-end-of-line (BEOL) processes due to the inability to remove molybdenum oxide (MoOₓ) in areas containing low-k materials. Mo materials/doping would allow for the formation of enhanced performance contact formed during middle-of-the-line (MOL) processes such as in logic applications. However, Mo surfaces when exposed to oxygen can form a layer of MoOₓ in areas of low-k dielectric materials that are highly susceptible to damage. Current processes lack any feasible approaches to reduce or remove the MoOₓ for BEOL without dealing significant damage to the surrounding low-k dielectric materials. For example, strong plasma treatments could fully reduce MoOₓ but would inevitably cause unacceptable damage to the low-k dielectric materials. As such, these approaches cannot be applied to BEOL applications.

Thus there is a need to develop new MoOₓ reduction processes for BEOL applications that do not damage the surrounding low-k materials.

### SUMMARY

Embodiments of the present disclosure generally relate to non-plasma methods of processing a substrate. More specifically, the methods disclosure herein incorporate a high pressure hydrogen soak to reduce a molybdenum oxide (MoOₓ) content in a semiconductor structure to molybdenum (metal).

In some embodiments, a method includes positioning a semiconductor structure within a processing chamber. The semiconductor structure includes a first layer disposed over a substrate surface. The first layer has a first dielectric layer. The semiconductor structure further includes a second layer disposed over the first layer. The second layer has a hardmask layer. The semiconductor structure further includes one or more second dielectric layers disposed over the second layer. The one or more second dielectric layers have a gap formed over a portion of the second layer. The semiconductor structure further includes a metal material disposed within the gap formed over the second layer. The metal material has a molybdenum oxide (MoOₓ) layer. The method further includes flowing a process gas into the processing chamber, and performing a redox operation on a portion of the semiconductor structure to reduce the MoOₓ to molybdenum (Mo). The redox operation includes applying a microwave energy to the process gas.

In some embodiments, a method includes positioning a semiconductor structure within a processing chamber. The semiconductor structure includes a first layer disposed over a substrate surface. The first layer has a tungsten based material. The semiconductor structure further includes one or more dielectric layers disposed over the first layer. The one or more dielectric layers include a gap formed over a portion of the first layer. The semiconductor structure further includes a metal material disposed within the gap over the first layer. The metal material has a molybdenum oxide (MoOₓ) layer. The method further includes performing a redox operation on a portion of the semiconductor structure to reduce the MoOₓ to molybdenum (Mo). Performing the redox operation includes flowing a process gas into the processing chamber, and applying a microwave energy to the process gas.

In some embodiments, a method includes positioning a semiconductor structure within a processing chamber. The semiconductor structure includes one or more dielectric layers disposed on a surface of a hardmask layer, and configured to form a gap over the hardmask layer. The one or more dielectric layers have a low-k dielectric material at a first carbon content. The semiconductor structure further includes a metal material disposed within the gap over the hardmask layer. The metal material has a first thickness and a first molybdenum oxide (MoOₓ) content. The method further includes flowing a process gas into the processing chamber. The method further includes performing a redox operation on the semiconductor structure by applying a microwave energy to the process gas to form a processed semiconductor structure. The processed semiconductor structure includes the low-k dielectric material at a second carbon content. The processed semiconductor structure further includes the metal material having a second thickness and a second MoOₓ content.

Embodiments of the disclosure will include a method that comprises positioning a semiconductor structure within a processing chamber, flowing a process gas into the processing chamber; and performing a redox operation on the semiconductor structure by applying a microwave energy to the process gas to form a processed semiconductor structure, wherein the process of applying the microwave energy to the process gas does not generate a plasma. The semiconductor structure comprising: one or more dielectric layers disposed on a surface of a hardmask layer; a gap formed through the one or more dielectric layers and the hardmask layer, the one or more dielectric layers comprising a low-k dielectric material at a first carbon content, and a metal material disposed within the gap, the metal material comprising a first thickness and a first molybdenum oxide (MoOₓ) content. The processed semiconductor structure comprising: the low-k dielectric material at a second carbon content, and the metal material comprising a second thickness and a second MoOₓ content.

Embodiments of the disclosure will include a method, comprising positioning a semiconductor structure within a processing volume of a processing chamber, wherein the semiconductor structure comprises: a first layer disposed over a substrate surface, the first layer comprising a first dielectric layer; one or more second dielectric layers disposed over the first layer, wherein the one or more second dielectric layers comprise a gap formed through the one or more second dielectric layers; and a metal material disposed within the gap and a portion of the first layer, the metal material comprising a molybdenum oxide (MoOₓ) layer. Then, flowing a process gas into the processing volume of the processing chamber, and performing a redox operation on a portion of the semiconductor structure to reduce the MoOₓ to molybdenum (Mo), wherein the redox operation comprises applying a microwave energy to the process gas. The application of the microwave energy does not generate a plasma within the processing volume.

Embodiments of the disclosure will include a method, comprising: positioning a semiconductor structure within a processing volume of a processing chamber, the semiconductor structure comprising: a first layer disposed over a substrate surface, the first layer comprising a tungsten based material, one or more dielectric layers disposed over the first layer, wherein the one or more dielectric layers comprise a gap formed over a portion of the first layer, and a metal material disposed within the gap over the first layer, the metal material comprising a molybdenum oxide (MoOₓ) layer; and performing a redox operation on a portion of the semiconductor structure to reduce the MoOₓ to molybdenum (Mo), wherein performing the redox operation comprises: flowing a process gas into the processing chamber; and applying a microwave energy to the process gas disposed within the processing volume, wherein the application of the microwave energy does not generate a plasma within the processing volume.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top view of a multi-chamber processing system, according to embodiments described herein.

FIG. 2A is a schematic of a processing chamber that includes a microwave source, in accordance with an embodiment.

FIG. 2B is a schematic of a solid state microwave emission module, in accordance with an embodiment.

FIG. 2C is a perspective view illustration of a source array for a microwave source, in accordance with an embodiment.

FIG. 2D is a cross-sectional illustration of a processing chamber for processing a semiconductor structure, in accordance with an embodiment.

FIG. 3 is a flow diagram depicting a method of processing a semiconductor structure, in accordance with an embodiment.

FIG. 4A is a cross-sectional illustration of a semiconductor structure, in accordance with an embodiment.

FIG. 4B is a cross-sectional illustration of a semiconductor structure, in accordance with an embodiment.

FIG. 5A is a cross-sectional transmission electron microscope (TEM) image of a semiconductor structure, in accordance with an embodiment.

FIG. 5B is a cross-sectional transmission electron microscope (TEM) image of a semiconductor structure, in accordance with an embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

Embodiments, of the present disclosure generally relate to methods for reducing a molybdenum oxide (MoOₓ) within a semiconductor structure to molybdenum (Mo) without damaging exposed materials within the semiconductor structure. Traditional methods of treat semiconductor structures having a MoOₓ layer include using either a remote plasma source or an inductively coupled plasma to generate active hydrogen species to actively remove the MoOₓ content present therein. However, such methods utilize harsh processing conditions that can damage other components of the semiconductor structure. The method disclosed herein utilizes a redox operation involving a H₂ soak of a substrate structure to convert MoOₓ present in a metal layer thereof to Mo without substantially damaging the surrounding low-k dielectric materials and/or additional metal material layers.

### Processing System Example

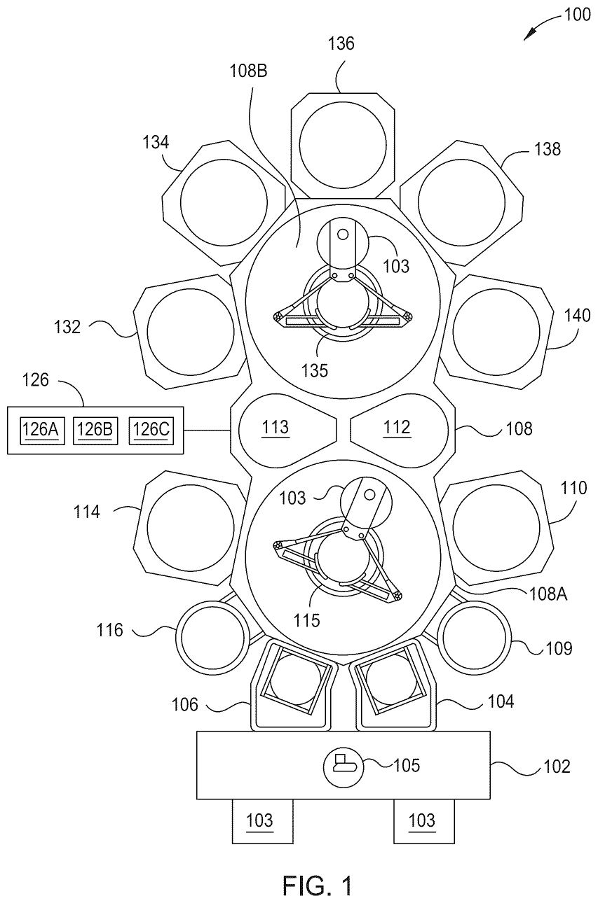

FIG. 1 illustrates a schematic representation of a processing system 100 for use with one or more embodiments of the disclosure. As detailed below, substrates in the processing system 100 may be processed in and transferred between the various chambers without exposing the substrates to an ambient environment exterior to the processing system 100 (for example, an atmospheric ambient environment such as may be present in a fab). For example, the substrates may be processed in and transferred between the various chambers maintained at a low pressure (for example, less than or equal to about 300 Torr) or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

Examples of a processing system that may be suitably modified in accordance with the teachings provided include the Endura®, Producer® or Centura® integrated processing systems or other suitable processing systems commercially available from Applied Materials, Inc., located in Santa Clara, California (CA), United States of America. One may envision that other processing systems, including those from other manufacturers, may be adapted to benefit from aspects described.

FIG. 1 is a schematic top view of the substrate processing system 100 (also referred to as a “processing platform”), according to embodiments described herein. The substrate processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the front opening unified pods (FOUPs) 103 to at least one of the first load lock chamber 104 or the second load lock chamber 106. Proceeding counterclockwise around the transfer chamber 108 from the buffer portion 108A of the first load lock chamber 104, the processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, a fourth processing chamber 138 and a fifth process chamber 140. In general, the processing chambers 132, 134, 136, 138, 140 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138, 140 are a PVD chamber. In some examples, the processing chamber 110 may be capable of performing an etch process, the processing chamber 114 may be capable of performing a cleaning process or an annealing process, and the processing chambers 132, 134, 136, 138, 140 may be capable of performing respective CVD or ALD deposition processes. In one example, the processing chambers 132, 134, 136, 138, or 140 may be a Volta™ CVD/ALD chamber, or Encore™ PVD chambers available from Applied Materials of Santa Clara, Calif.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr, and will typically be maintained at pressures near 10⁻⁵ Torr (that is, ˜10⁻³ Pa). However, some high-vacuum systems may operate below near 10⁻⁷ Torr (that is, ˜10⁻⁵ Pa). In certain embodiments, the vacuum is created using a rough pump and/or a turbomolecular pump coupled to the transfer chamber 108 and to each of the one or more process chambers (for example, process chambers 109-140). However, other types of vacuum pumps are also contemplated.

A system controller 126, such as a programmable computer, is coupled to the processing system 100 for controlling one or more of the components therein. For example, the system controller 126 may control the operation of one or more of the processing chambers, such as processing chambers 132, 134, 136, 138, 140. In operation, the system controller 126 enables data acquisition and feedback from the respective components to coordinate processing in the processing system 100.

The system controller 126 includes a programmable central processing unit (CPU) 126A, which is operable with a memory 126B (for example, non-volatile memory) and support circuits 126C. The support circuits 126C (for example, cache, clock circuits, input/output subsystems, power supplies, etc., and combinations thereof) are conventionally coupled to the CPU 126A and coupled to the various components within the processing system 100.

In some embodiments, the CPU 126A is one of any form of general purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (for example, non-volatile memory), that when executed by the CPU 126A, facilitates the operation of the processing system 100. The instructions in the memory 126B are in the form of a program product such as a program that implements the methods of the present disclosure (for example, middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (for example, read-only memory devices within a computer such as CD-ROM disks readable by a CD-ROM drive, flash memory, ROM chips or any type of solid-state non-volatile semiconductor memory) on which information is permanently stored; and (ii) writable storage media (for example, floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. The various methods disclosed herein may generally be implemented under the control of the CPU 126A by the CPU 126A executing computer instruction code stored in the memory 126B (or in memory of a particular processing chamber) as, for example, a software routine. When the computer instruction code is executed by the CPU 126A, the CPU 126A controls the chambers to perform processes in accordance with the various methods.

As will be described further below, in one or more embodiments of the substrate processing sequence described herein, all of the processes are performed under vacuum within the processing system 100. In one example of the processing system 100, a remote-plasma-source (RPS) cleaning process is performed in chamber 110, a precleaning process is performed in chamber 114, and one or more of a deposition, an etching, and/or a thermal processing process is performed in at least one of the chambers 132, 134, 136, 138, and 140. In one example, the remote plasma (RPS) assisted process performed in chamber 110 is performed in a processing chamber, such as Aktiv™ Preclean (APC) chamber available from Applied Materials of Santa Clara, Calif. In another example, the processing chambers 132, 134, 136, 138, or 140 may be a Volta™ CVD/ALD chamber, or Encore™ PVD chambers available from Applied Materials of Santa Clara, Calif.

In another example of the processing system 100, a remote-plasma-source (RPS) cleaning process and a precleaning process are both performed in at least one of the chambers 110 and 114, and one or more of a deposition, an etching, and/or a thermal processing process is performed in at least one of the chambers 132, 134, 136, 138, and 140. In one example, the processing chambers 132, 134, 136, 138, or 140 may be a Volta™ CVD/ALD chamber, or Encore™ PVD chambers available from Applied Materials of Santa Clara, Calif.

### Processing Chamber Example.

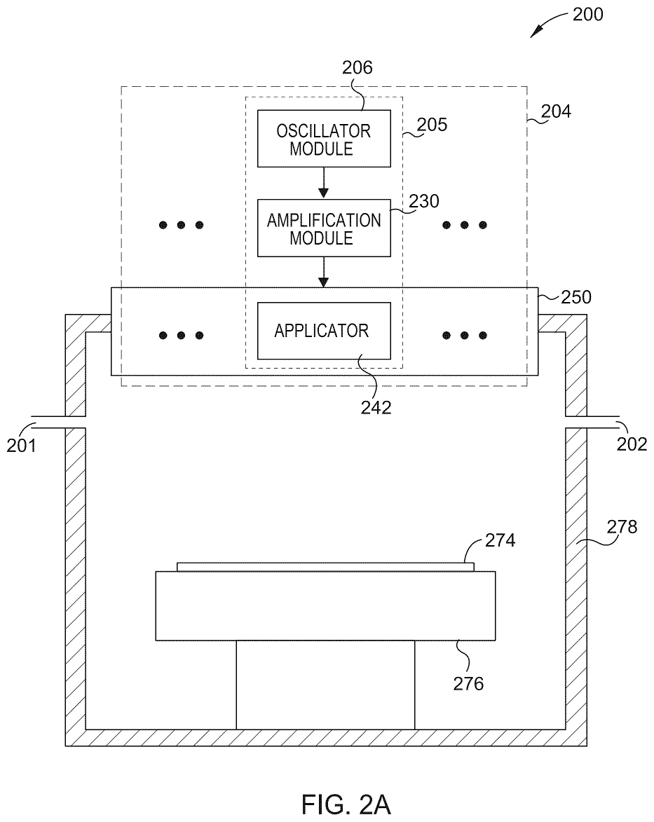

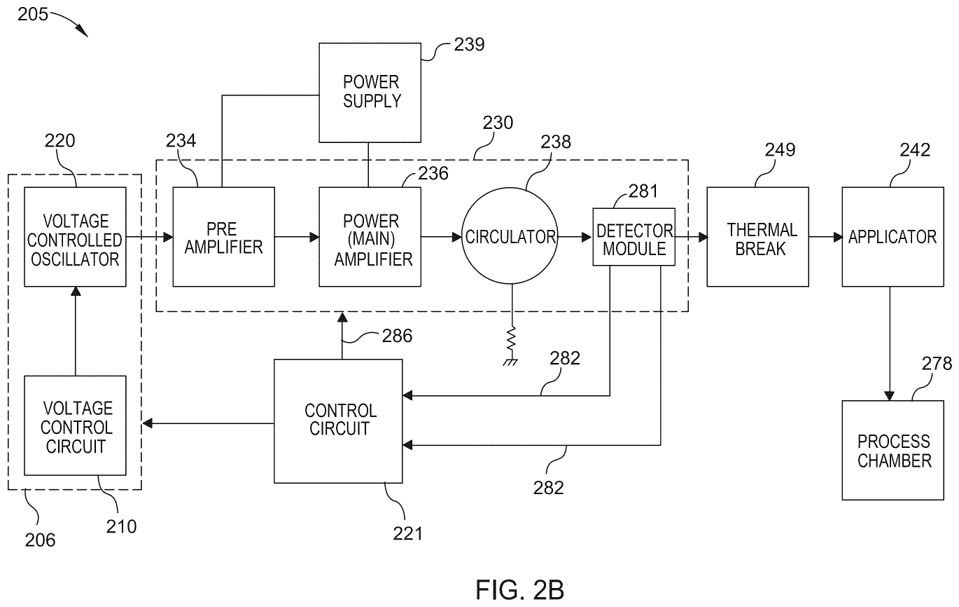

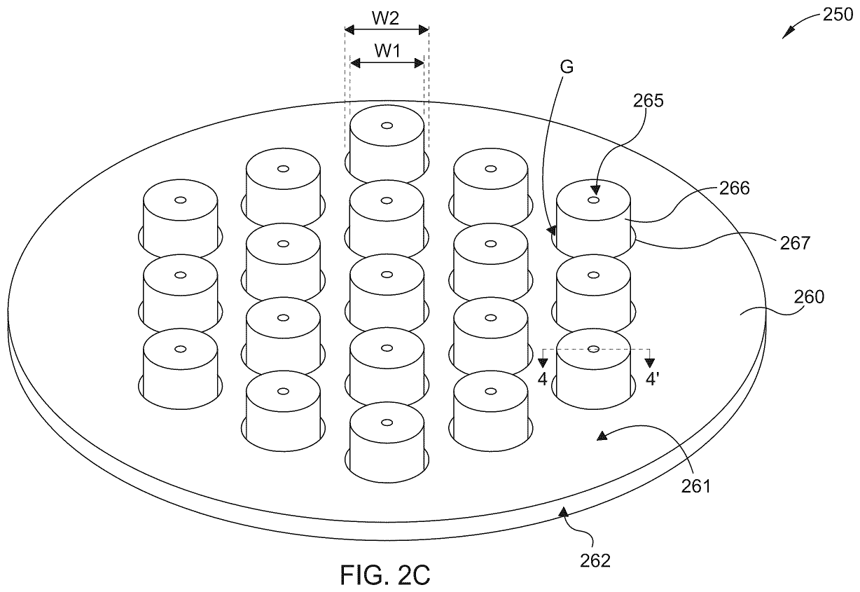

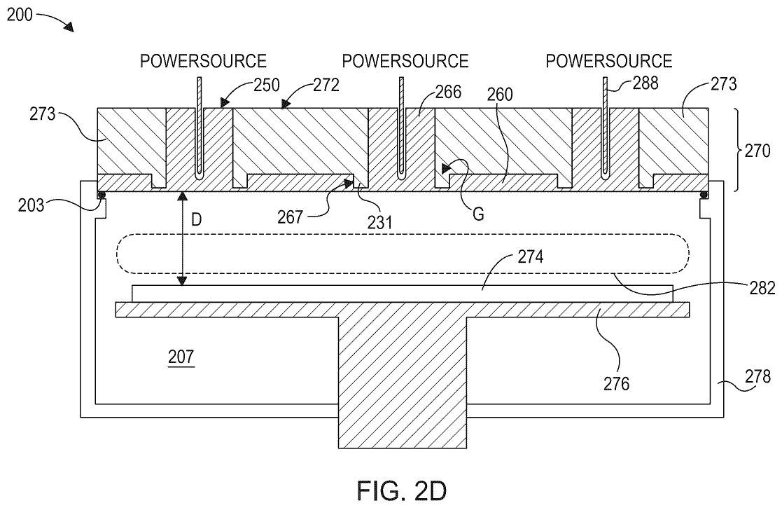

Referring now to FIGS. 2A-2D, a series of illustrations depicting an example of a microwave processing tool 200 is shown, in accordance with an embodiment. The microwave processing tool 200 is configured to deliver microwave energy to a processing region of the process chamber to perform a low temperature preclean process on a substrate.

Referring now to FIG. 2A, a cross-sectional illustration of a microwave processing tool 200 (referred to as processing tool 200 for short) is shown, according to an embodiment. In some embodiments, the processing tool 200 may be a processing tool suitable for any type of processing operation that requires the delivery of microwave energy. In some embodiments, one or more of the chambers 110 and 114, or even chambers 132-140, may include the processing tool 200. The processing tool may emit high-frequency electromagnetic radiation in the form of microwave energy. In some embodiments, “High-frequency” may refer to frequencies between 300 MHz and 1000 GHz.

Generally, embodiments include a processing tool 200 that includes a chamber 278. In processing tool 200, the chamber 278 may be a vacuum chamber. A vacuum chamber may include a pump (not shown) for removing gases from the chamber to provide the desired vacuum. Additional embodiments may include a chamber 278 that includes one or more gas lines 201 for providing processing gasses into the chamber 278 and exhaust lines 202 for removing byproducts from the chamber 278. While not shown, it is to be appreciated that gas may also be injected into the chamber 278 through a source array 250 (e.g., as a showerhead) for evenly distributing the processing gases over a substrate 274.

In an embodiment, the substrate 274 may be supported on a chuck 276. For example, the chuck 276 may be any suitable chuck, such as an electrostatic chuck. The chuck 276 may also include cooling lines and/or a heater to provide temperature control to the substrate 274 during processing. Due to the modular configuration of the high-frequency emission modules described herein, embodiments allow for the processing tool 200 to accommodate any sized substrate 274. For example, the substrate 274 may be a semiconductor wafer (e.g., 200 mm, 300 mm, 450 mm, or larger). Alternative embodiments also include substrates 274 other than semiconductor wafers. For example, embodiments may include a processing tool 200 configured for processing glass substrates (e.g., for display technologies).

According to an embodiment, the processing tool 200 includes a modular high-frequency emission source 204. The modular high-frequency emission source 204 may comprise an array of high-frequency emission modules 205. In an embodiment, each high-frequency emission module 205 may include an oscillator module 206, an amplification module 230, and an applicator 242. As shown, the applicators 242 are schematically shown as being integrated into the source array 250.

In an embodiment, the oscillator module 206 and the amplification module 230 may comprise electrical components that are solid state electrical components. In an embodiment, each of the plurality of oscillator modules 206 may be communicatively coupled to different amplification modules 230. For example, each oscillator module 206 may be electrically coupled to a single amplification module 230. In an embodiment, the plurality of oscillator modules 206 may generate incoherent electromagnetic radiation. Accordingly, the electromagnetic radiation induced in the chamber 278 will not interact in a manner that results in an undesirable interference pattern.

In an embodiment, each oscillator module 206 generates high frequency electromagnetic radiation that is transmitted to the amplification module 230. After processing by the amplification module 230, the electromagnetic radiation is transmitted to the applicator 242. In an embodiment, the applicators 242 each emit electromagnetic radiation into the chamber 278. In some embodiments, the applicators 242 couple the electromagnetic radiation to the processing gasses in the chamber 278 to provide energy thereto, without forming a plasma.

Referring now to FIG. 2B, a schematic of a solid state high-frequency emission module 205 is shown, in accordance with an embodiment. In an embodiment, the high-frequency emission module 205 comprises an oscillator module 206. The oscillator module 206 may include a voltage control circuit 210 for providing an input voltage to a voltage controlled oscillator 220 in order to produce high-frequency electromagnetic radiation at a desired frequency. The voltage controlled oscillator 220 is an electronic oscillator whose oscillation frequency is controlled by the input voltage. According to an embodiment, the input voltage from the voltage control circuit 210 results in the voltage controlled oscillator 220 oscillating at a desired frequency.

According to an embodiment, the electromagnetic radiation is transmitted from the voltage controlled oscillator 220 to an amplification module 230. The amplification module 230 may include a driver/pre-amplifier 234, and a main power amplifier 236 that are each coupled to a power supply 239. According to an embodiment, the amplification module 230 may operate in a pulse mode. For example, the amplification module 230 may have a duty cycle between 1% and 99%. In a more particular embodiment, the amplification module 230 may have a duty cycle between approximately 15% and 50%.

In an embodiment, the electromagnetic radiation may be transmitted to the thermal break 249 and the applicator 242 after being processed by the amplification module 230. However, part of the power transmitted to the thermal break 249 may be reflected back due to the mismatch in the output impedance. Accordingly, some embodiments include a detector module 281 that allows for the level of forward power 283 and reflected power 282 to be sensed and fed back to the control circuit module 221. It is to be appreciated that the detector module 281 may be located at one or more different locations in the system (e.g., between the circulator 238 and the thermal break 249). In an embodiment, the control circuit module 221 interprets the forward power 283 and the reflected power 282, and determines the level for the control signal 285 that is communicatively coupled to the oscillator module 206 and the level for the control signal 286 that is communicatively coupled to the amplification module 230. In an embodiment, control signal 285 adjusts the oscillator module 206 to optimize the high-frequency radiation coupled to the amplification module 230. In an embodiment, control signal 286 adjusts the amplification module 230 to optimize the output power coupled to the applicator 242 through the thermal break 249. In an embodiment, the feedback control of the oscillator module 206 and the amplification module 230, in addition to the tailoring of the impedance matching in the thermal break 249, may allow for the level of the reflected power to be less than approximately 5% of the forward power. In some embodiments, the feedback control of the oscillator module 206 and the amplification module 230 may allow for the level of the reflected power to be less than approximately 2% of the forward power.

Accordingly, embodiments allow for an increased percentage of the forward power to be coupled into the processing chamber 278, and increases the available power provided to the process gases disposed within the processing volume. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator.

Referring now to FIG. 2C, a perspective view illustration of a source array 250 is shown, in accordance with an embodiment. In an embodiment, the source array 250 comprises a dielectric plate 260. A plurality of cavities 267 are disposed into a first surface 261 of the dielectric plate 260. The cavities 267 do not pass through to a second surface 262 of the dielectric plate 260. The source array 250 may further include a plurality of dielectric resonators 266. Each of the dielectric resonators 266 may be in a different one of the cavities 267. Each of the dielectric resonators 266 may comprise a hole 265 in the axial center of the dielectric resonator 266.

In an embodiment, the dielectric resonators 266 may have a first width W1, and the cavities 267 may have a second width W2. The first width W1 of the dielectric resonator 266 is smaller than the second width W2 of the cavities 267. The difference in the widths provides a gap G between a sidewall of the dielectric resonators 266 and a sidewall of the cavity 267. In the illustrated embodiment, each of the dielectric resonators 266 are shown as having a uniform width W1. However, it is to be appreciated that not all dielectric resonators 266 of a source array 250 need to have the same dimensions.

Referring now to FIG. 2D, a cross-sectional illustration of a processing tool 200 that includes an assembly 270 is shown, in accordance with an embodiment. In an embodiment, the processing tool comprises a chamber 278 that is sealed by an assembly 270. For example, the assembly 270 may rest against one or more O-rings 203 to provide a vacuum seal to an interior chamber volume 207 of the chamber 278. In other embodiments, the assembly 270 may interface with the chamber 278. That is, the assembly 270 may be part of a lid that seals the chamber 278. In an embodiment, the processing tool 200 may comprise a plurality of processing volumes (which may be fluidically coupled together), with each processing volume having a different assembly 270. In an embodiment, a chuck 279 or the like may support a substrate 274. The substrate 274 may be a distance D from the assembly 270. In an embodiment, the interior chamber volume 207 may be suitable for delivering microwave energy to a process gas disposed within the chamber 278. That is, the chamber 278 may be a vacuum chamber.

In an embodiment, the assembly 270 comprises a source array 250 and a housing 272. The source array 250 may comprise a dielectric plate 260 and a plurality of dielectric resonators 266 extending up from the dielectric plate 260. Cavities 267 into the dielectric plate 260 may surround each of the dielectric resonators 266. Sidewalls of the cavity 267 are separated from the sidewall of the dielectric resonator 266 by a gap G. The dielectric plate 260 and the dielectric resonators 266 of the source array 250 may be a monolithic structure (as shown in FIG. 2D), or the dielectric plate 260 and the dielectric resonators 266 may be discrete components.

The housing 272 include rings 231 that fit into the gaps G. In an embodiment, the rings 231 and the conductive body 273 of the housing 272 are a monolithic structure (as shown in FIG. 2D), or the conductive body 273 and the rings 231 may be discrete components. The housing 272 may having openings sized to receive the dielectric resonators 266. In an embodiment, monopole antennas 288 may extend into holes in the dielectric resonators 266. The monopole antennas 288 are each electrically coupled to power sources (e.g., high-frequency emission modules 205).

### Substrate Processing Sequences

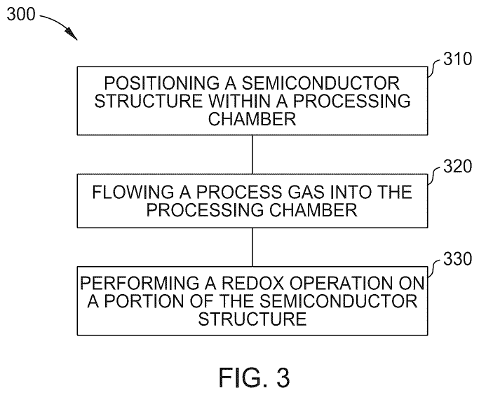

FIG. 3 depicts a process flow diagram of a method 300 of processing a substrate to, for example, form middle-of-line (MOL) and back-end-of-line (BEOL) structures, according to one or more embodiments of the present disclosure. The method 300 includes positioning a semiconductor structure within a processing chamber (operation 310), flowing a process gas into the process chamber (operation 320), and performing a redox operation on a portion of the semiconductor structure (operation 330).

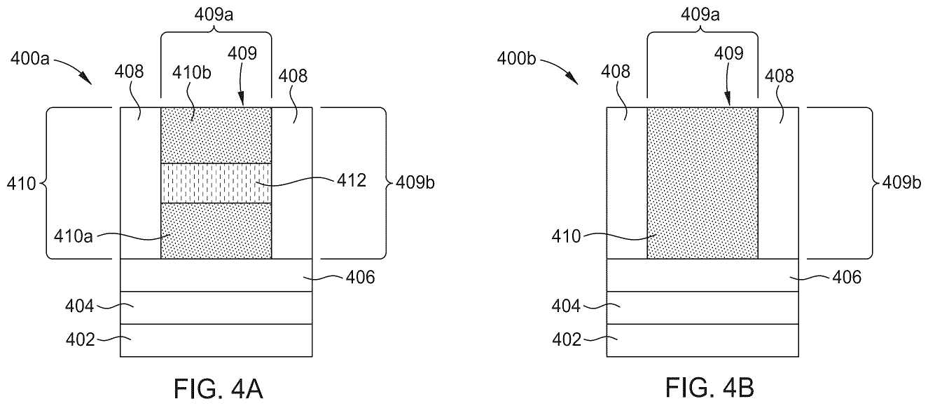

FIGS. 4A-4B illustrate cross-sectional views of a semiconductor structure (e.g., 400a and 400b, respectively) in accordance with one or more embodiments described herein. Although FIGS. 4A-4B are described in relation to the method 300, the structures disclosed in FIGS. 4A-4B are not limited to the method 300, but instead may stand alone as structures independent of the method 300. Similarly, although the method 300 is described in relation to FIGS. 4A-4B, the method 300 is not limited to the structures disclosed in FIGS. 4A-4B but instead may stand alone independent of the structures disclosed in FIGS. 4A-4B. It should be understood that FIGS. 4A-4B illustrate only partial schematic views of the semiconductor device structure (e.g., 400a and 400b, respectively), and the semiconductor device structure (e.g., 400a and 400b, respectively) may contain any number of transistors or other devices and additional materials having aspects as illustrated in the figures. It should also be noted that although the method 300 illustrated in FIG. 3 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

FIG. 4A depicts a semiconductor structure 400a prior to undergoing the method 300. The semiconductor structure 400a may include a SiO₂ layer 404 deposited on a substrate surface 402. The semiconductor structure 400a may also include a hardmask layer 406 deposited over the SiO₂ layer 404. The semiconductor structure 400a may also include one or more layers 408 deposited over the surface of the hardmask layer 406. The one or more layers 408 may independently include a low-k dielectric material. The low-k dielectric material may include a silicon carbide oxide material or a carbon doped silicon oxide material, for example BLACK DIAMOND® II low-k dielectric material, available from Applied Materials, Inc., located in Santa Clara, California.

In some embodiments, the one or more layers 408 may be organized and/or deposited in such a way to provide a gap 409 to the surface of the semiconductor structure 400a, thus producing a textured/patterned surface to the semiconductor structure 400a. The one or more layers 408 of the semiconductor structure 400a may be organized such that the gap 409 has a gap width 409a (e.g., distance/space between the interior surfaces of a feature formed in the one or more layers 408) of about 10 nm to about 50 nm, such as about 20 nm to about 40 nm, such as about 25 nm to about 35 nm, alternatively about 10 nm to about 20 nm, alternatively about 20 nm to about 25 nm, alternatively about 25 nm to about 30 nm, alternatively about 30 nm to about 35 nm, alternatively about 35 nm to about 40 nm, alternatively about 40 nm to about 50 nm. In at least one embodiment, the gap 409 has a gap height 409b (e.g., distance between the surface of the hardmask layer 406 and the top surface of the one or more layers 408) of about 20 nm to about 100 nm, such as about 40 nm to about 80 nm, such as about 50 nm to about 70 nm, alternatively about 20 nm to about 40 nm, alternatively about 40 nm to about 50 nm, alternatively about 50 nm to about 60 nm, alternatively about 60 nm to about 70 nm, alternatively about 70 nm to about 80 nm, alternatively about 80 nm to about 100 nm.

In some embodiments, the semiconductor structure 400a includes a metal material 410 deposited in the gap 409 formed by the one or more layers 408. The metal material 410 may include one or more metal layers, such as one or more molybdenum (Mo) based layers, deposited in the gap 409 formed by the one or more layers 408. For example, the metal material 410 of the semiconductor structure 400a can include, but is not limited to, a first layer 410a deposited over a contact metal layer (not shown) or an interconnect metal layer (not shown) and in some cases a portion of the hardmask layer 406, a second layer 412 disposed over the first layer 410a, and a third layer 410b over disposed over the second layer 412. In at least one embodiment, the first layer 410a and the third layer 410b include the same material (e.g., Mo). The first layer 410a may include a Mo layer deposited via a chemical vapor deposition (CVD) process. The second layer 412 may include a molybdenum oxide (MoOₓ). The third layer 410b may include a Mo layer deposited via a physical vapor deposition (PVD) process. In some embodiments, the gap 409 is substantially filled with metal material 410 such that the gap width 409a and the gap height 409b is substantially encompassed with the metal material 410. The height and width of the metal material 410, and/or the one or more metal layers thereof, may be substantially the same as the gap width 409a and the gap height 409b.

In some embodiments, the semiconductor structure 400a includes a MoOₓ layer (e.g., second layer 412) resulting from one or more semiconductor fabrication/processing procedures. It may be desired to remove the MoOₓ layer (e.g., second layer 412) from the semiconductor structure 400a without reducing the height or width of the metal material 410 within the gap 409. Furthermore, removal of such MoOₓ layers should not come at the expense of damaging the low-k dielectric materials of the one or more layers 408. As such, the method 300 for processing a semiconductor structure (e.g., semiconductor structure 400a) utilizes a redox operation to convert the MoOₓ layer (e.g., second layer 412) to a Mo containing layer via a reduction reaction.

Referring back to the method 300, operation 310 includes positioning a semiconductor structure 400a into a processing chamber. At operation 320, a process gas is flowed into the processing chamber. The process gas may include hydrogen (H₂), Ar, He, water (H₂O), or a combination thereof. In at least one embodiment, the process gas includes H₂. The process gas may be flowed into the processing chamber at a gas flow rate of about 0.01 sccm to about 45,000 sccm, such as about 100 sccm to about 45,000 sccm, such as about 1,000 sccm to about 45,000 sccm, such as about 2,000 sccm to about 45,000 sccm, such as about 3,000 sccm to about 45,000 sccm, such as about 10,000 sccm to about 45,000 sccm, alternatively about 0.01 sccm to about 100 sccm, alternatively about 100 sccm to about 1,000 sccm, alternatively about 1,000 sccm to about 2,000 sccm, alternatively about 2,000 sccm to about 3,000 sccm, alternatively about 3,000 sccm to about 10,000 sccm, alternatively about 10 sccm to about 2,000 sccm. In at least one embodiment, the process gas is flown into the processing chamber continuously throughout the duration of the method 300.

At operation 330 of the method 300, a redox operation is performed on the semiconductor structure 400a to convert the MoOₓ layer to a Mo layer. During the redox operation of operation 330, the temperature within the processing chamber may be from about 100° C. to about 500° C., such as about 150° C. to about 450° C., such as about 200° C. to about 400° C., such as about 250° C. to about 350° C., alternatively about 100° C. to about 150° C., alternatively about 150° C. to about 200° C., alternatively about 200° C. to about 250° C., alternatively about 250° C. to about 300° C., alternatively about 300° C. to about 350° C., alternatively about 350° C. to about 400° C., alternatively about 400° C. to about 450° C., alternatively about 450° C. to about 500° C. The pressure within the processing chamber during the redox operation may be from about 10 Torr to about 760 Torr, such as about 250 Torr to about 760 Torr, such as about 250 Torr to about 530 Torr, alternatively about 10 Torr to about 100 Torr, alternatively about 100 Torr to about 250 Torr, alternatively about 250 Torr to about 400 Torr, alternatively about 400 Torr to about 550 Torr, alternatively about 500 Torr to about 760 Torr, alternatively about 100 Torr to about 760 Torr. The redox operation of operation 330 may be performed for about 1 second(s) to about 360 s, such as about 60 s to about 300 s, such as about 120 s to about 240 s, alternatively about 1 s to about 60 s, alternatively about 60 s to about 120 s, alternatively about 120 s to about 180 s, alternatively about 180 s to about 240 s, alternatively about 240 s to about 300 s, alternatively about 300 s to about 360 s.

In some embodiments, a microwave energy is applied to the process gas during the redox operation of operation 330. In at least one embodiment, applying the microwave energy to the process gas induces a plasma within the processing chamber. In at least one embodiment, the microwave energy applied during processing is provided at a power level at which the delivered microwave energy does not generate a plasma. Without being bound by theory, the delivery of microwave energy that is at a non-plasma generating power level can significantly reduce the amount of damage to the materials (e.g., dielectric and metal materials) in the semiconductor structure due to plasma generated ion bombardment of the materials within the semiconductor structure. By using a non-plasma generating mode, the low-k damage can be 10% to 50% lower than the plasma mode, as the energetic species (e.g., hydrogen radicals and ions) are not introduced during the process. In one example, a non-plasma generating power level will include a microwave energy power level that is between 1% and 10% below a lowest power level that generates a plasma during a process that includes a desired gas composition and pressure level. The microwave energy applied to the process gas during the redox operation may be applied at a power of about 0.1 W to about 150 W, such as about 1 W to about 150 W, such as about 10 W to about 150 W, such as about 100 W to about 150 W at a frequency greater than 2.0 GHz, such as between about 2.0 GHz and 2.5 GHz. The microwave energy may be applied to the process gas continuously throughout the redox operation 330. In at least one embodiment, the redox operation includes applying the microwave energy to the process gas for about 1 s to about 360 s, such as about 60 s to about 300 s, such as about 120 s to about 240 s, alternatively about 1 s to about 60 s, alternatively about 60 s to about 120 s, alternatively about 120 s to about 180 s, alternatively about 180 s to about 240 s, alternatively about 240 s to about 300 s, alternatively about 300 s to about 360 s.

In at least one embodiment, the processing chamber is purged after operation 330 to remove contaminants therefrom. In at least one embodiment, operation 330 may be repeated such that the semiconductor structure 400a undergoes multiple redox operation cycles. In such instances, operation 330 may be performed for 1 cycle to about 30 cycles, such as for 1 cycle to 15 cycles, such as for 1 cycle to 10 cycles, such as for 1 cycle to 5 cycles.

Unlike conventional plasma treatment processes (e.g., remote plasma and/or inductively coupled plasma sources), the redox operation of operation 330 may be conducted at higher pressures relative to such processes. Such high pressures require higher process gas flows to maintain such pressure. The processing conditions of the redox operation can provide an alternative treatment route for removing/treating semiconductor structures having a MoOₓ content. Notably, the processing conditions of the redox operation can treat semiconductor structures having a MoOₓ content at a higher treatment efficiency while also limiting the damage applied to the low-k dielectric material, as compared to conventional plasma treatment processes. Furthermore, the redox operation of operation 330 may include applying a microwave energy to the process gas introduced to the processing chamber. The microwave energy may be applied to the process gas at a non-plasma generating power level so as to not induce the formation of a plasma over a surface of a substrate. In doing so, the processing conditions described herein can provide comparable and/or enhanced MoOₓ content reduction and limited damage to the surrounding low-k dielectric material as convention plasma treatment processes without the need to form a potentially damaging plasma.

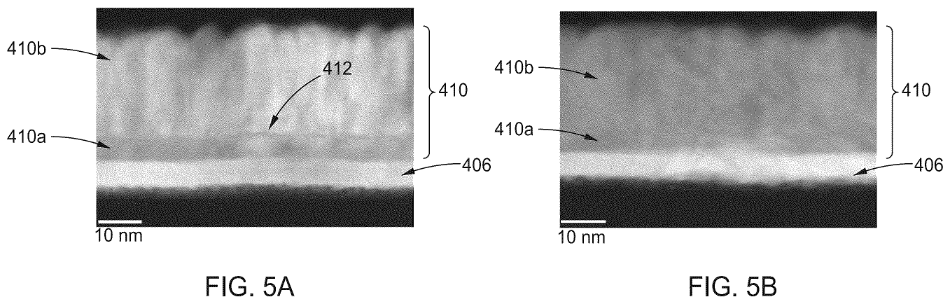

FIG. 4B illustrates a semiconductor structure 400b that has been subjected to the method 300. As shown, the MoOₓ layer (e.g., second layer 412) of the metal material 410 deposited in the gap 409 of the semiconductor structure 400a is absent in the semiconductor structure 400b. The absence of the MoOx layer in the semiconductor structure 400b is due to the redox operation reducing the MoOₓ to Mo (metallic) to form a Mo layer having no distinguishable interface between the first layer 410a and third layer 410b of the metal material 410. This is further illustrated in FIGS. 5A and 5B.

FIG. 5A shows a transmission electron microscope (TEM) image of a semiconductor structure (e.g., semiconductor structure 400a) prior to undergoing the method 300. As can be observed, the semiconductor structure shown in FIG. 5A includes a hardmask layer 406 comprised of tungsten and a metal material 410 disposed over the hardmask layer. The metal material 410 of the semiconductor structure includes a first layer 410a composed of a CVD deposited molybdenum and a third layer 410b composed of a PVD deposited molybdenum layer. The first layer 410a and the third layer 410b are separated by a second layer 412 composed of MoOₓ, which can be observed as an interface between first layer 410a and the third layer 410b. FIG. 5B shows a TEM image of the semiconductor structure (e.g., semiconductor structure 400b) after being subjected to the method 300. As is shown, no distinguishable interface can be observed between the first layer 410a and the third layer 410b. As previously discussed, the method 300 reduces the MoOₓ layer to Mo such that each of the layers (e.g., the first layer 410a, the second layer 412, and the third layer 410b) of the metal material 410 are substantially composed of the same material. Thus, no distinguishable interface can be observed within the metal material 410.

In at least one embodiment, greater than about 80% of the MoOₓ within the metal material 410 is reduced to Mo after subjecting a semiconductor structure to the method 300, such as greater than about 85%, such as greater than about 90%, such as greater than about 95%, such as greater than about 99.9%. In some embodiments, about 80% to about 99.9% of the MoOₓ within the metal material 410 is reduced to Mo after subjecting a semiconductor structure to the method 300, such as about 85% to about 95%, such as about 87.5% to about 92.5%, alternatively about 80% to about 85%, such as about 85% to about 87.5%, such as about 87.5% to about 90%, such as about 90% to about 92.5%, such as about 92.5% to about 95%, such as about 95% to about 99.9%. In at least one embodiment, the final MoOₓ content within the metal material 410 (e.g., after undergoing the method 300) is about 80% to about 99.9% less than the initial MoOₓ content, such as about 85% to about 95% less, such as about 87.5% to about 92.5% less, alternatively about 80% to about 85% less, such as about 85% to about 87.5% less, such as about 87.5% to about 90% less, such as about 90% to about 92.5% less, such as about 92.5% to about 95% less, such as about 95% to about 99.9% less.

In some embodiments, the metal layer 410 has a thickness (as determined in relation to the gap height 409b) of about 100 Å to about 500 Å prior to undergoing the method 300, such as about 150 Å to about 450 Å, such as about 200 Å to about 400 Å, such as about 250 Å to about 350 Å, alternatively about 100 Å to about 150 Å, alternatively about 150 Å to about 200 Å, alternatively about 200 Å to about 250 Å, alternatively about 250 Å to about 300 Å, alternatively about 300 Å to about 350 Å, alternatively about 350 Å to about 400 Å, alternatively about 400 Å to about 450 Å, alternatively about 450 Å to about 500 Å. After being subjected to the method 300, the metal layer 410 has a thickness of about 100 Å to about 500 Å prior to undergoing the method 300, such as about 150 Å to about 450 Å, such as about 200 Å to about 400 Å, such as about 250 Å to about 350 Å, alternatively about 100 Å to about 150 Å, alternatively about 150 Å to about 200 Å, alternatively about 200 Å to about 250 Å, alternatively about 250 Å to about 300 Å, alternatively about 300 Å to about 350 Å, alternatively about 350 Å to about 400 Å, alternatively about 400 Å to about 450 Å, alternatively about 450 Å to about 500 Å. In at least one embodiment, the metal material 410 retains greater than about 60% of its initial thickness after undergoing the method 300, such as greater than about 70%, such as greater than about 80%, such as greater than about 90%, such as greater than about 95%, such as greater than about 99.9%. In at least one embodiment, the metal material 410 retains about 60% to about 90% of its initial thickness after undergoing the method 300, such as about 65% to about 85%, such as about 70% to about 80%, alternatively about 60% to about 65%, alternatively about 65% to about 70%, alternatively about 70% to about 75%, alternatively about 75% to about 80%, alternatively about 80% to about 85%, alternatively about 85% to about 90%. In at least one embodiment, the final thickness of the metal material 410 (e.g., after undergoing the method 300) is about 60% to about 90% less than the initial thickness, such as about 65% to about 85% less, such as about 70% to about 80% less, alternatively about 60% to about 65% less, alternatively about 65% to about 70% less, alternatively about 70% to about 75% less, alternatively about 75% to about 80% less, alternatively about 80% to about 85% less, alternatively about 85% to about 90% less.

As previously discussed, the removal of such MoOₓ layers should not come at the expense of damaging the low-k dielectric materials of the one or more layers 408. That is to say that the one or more layers 408 formed from the low-k dielectric materials should experience a minimized and/or eliminated loss in carbon content as a result of undergoing the method 300. In some embodiments, the method 300 results in a carbon loss of less than 1%, such as less than about 0.5%, such as less than about 0.1%, such as less than about 0.01%, such as less than about 0.001%. In at least one embodiment, the method 300 results in a carbon loss of about 0.001% to about 1%, such as about 0.01 to about 1%, such as about 0.1% to about 1%, such as about 0.5 % to about 1%, alternatively about 0.001% to about 0.01%, alternatively about 0.01% to about 0.1%, alternatively about 0.1% to about 0.5%. In at least one embodiment, the final carbon content of the one or more layers 408 (e.g., after undergoing the method 300) is about 0.001% to about 1% less than the initial carbon content, such as about 0.01 to about 1% less, such as about 0.1% to about 1% less, such as about 0.5 % to about 1% less, alternatively about 0.001% to about 0.01% less, alternatively about 0.01% to about 0.1% less, alternatively about 0.1% to about 0.5% less.

Overall, the methods disclosed herein provide a minimally destructive and/or non-destructive hydrogen treatment for converting MoOₓ to Mo. The method disclosed herein utilizes a redox operation involving a H₂ soak of a substrate structure to convert MoOₓ present in a metal layer thereof to Mo without substantially damaging the surrounding low-k dielectric materials and/or additional metal material layers. In some instances, the redox operation includes applying a microwave energy to a process gas to enhance the conversion of MoOₓ to Mo. The microwave energy may be applied to the process gas so to not induce the formation of a plasma. The processing conditions described herein can provide comparable and/or enhanced MoOₓ content reduction and limited damage to the surrounding low-k dielectric material as convention plasma treatment processes without the need to form a potentially damaging plasma.

While the foregoing is directed to embodiments of the present disclosure, other and further embodiments of the disclosure may be devised without departing from the basic scope thereof, and the scope thereof is determined by the claims that follow.

We claim:

1. A method, comprising:
positioning a semiconductor structure within a processing volume of a processing chamber, the semiconductor structure comprising:
a first layer disposed over a substrate surface, the first layer comprising a first dielectric layer;
one or more second dielectric layers disposed over the first layer, wherein the one or more second dielectric layers comprise a gap formed through the one or more second dielectric layers; and
a metal material disposed within the gap and a portion of the first layer, the metal material comprising a molybdenum oxide (MoOₓ) layer;
flowing a process gas into the processing volume of the processing chamber; and
performing a redox operation on a portion of the semiconductor structure to reduce the MoOₓ to molybdenum (Mo), wherein the redox operation comprises applying a microwave energy to the process gas.

2. The method of claim 1, wherein the application of the microwave energy does not generate a plasma within the processing volume.

3. The method of claim 2, wherein the process gas is selected from the group consisting of hydrogen (H₂), and water (H₂O).

4. The method of claim 3, wherein the microwave energy is provided at a frequency greater than 2.0 GHz.

5. The method of claim 1, wherein
the process gas is selected from the group consisting of hydrogen (H₂), and water (H₂O),
a temperature within the processing chamber is about 100° C. to about 500° C., and
the microwave energy is applied at a power of about 0.1 W to about 150 W.

6. The method of claim 5, wherein a pressure within the processing chamber is about 10 Torr to about 760 Torr.

7. A method, comprising:
positioning a semiconductor structure within a processing volume of a processing chamber, the semiconductor structure comprising:
a first layer disposed over a substrate surface, the first layer comprising a tungsten based material,
one or more dielectric layers disposed over the first layer, wherein the one or more dielectric layers comprise a gap formed over a portion of the first layer, and
a metal material disposed within the gap over the first layer, the metal material comprising a molybdenum oxide (MoOₓ) layer; and
performing a redox operation on a portion of the semiconductor structure to reduce the MoOₓ to molybdenum (Mo), wherein performing the redox operation comprises:
flowing a process gas into the processing chamber; and
applying a microwave energy to the process gas disposed within the processing volume, wherein the application of the microwave energy does not generate a plasma within the processing volume.

8. The method of claim 7, wherein the process gas is selected from the group consisting of hydrogen (H₂), and water (H₂O).

9. The method of claim 7, wherein the microwave energy is applied at a frequency greater than about 2.0 GHz and at a power of about 0.1 W to about 150 W.

10. The method of claim 9, wherein the process gas is selected from the group consisting of hydrogen (H₂), and water (H₂O).

11. The method of claim 7, wherein the process gas is flowed into the processing chamber at a gas flow rate of about 0.01 sccm to about 45,000 sccm.

12. The method of claim 11, wherein a temperature within the processing chamber is about 100° C. to about 500° C.

13. The method of claim 12, wherein a pressure within the processing chamber is about 10 Torr to about 760 Torr.

14. The method of claim 13, wherein the redox operation is performed for about 1 s to about 360 s.

15. A method, comprising:
positioning a semiconductor structure within a processing chamber, the semiconductor structure comprising:
one or more dielectric layers disposed on a surface of a hardmask layer;
a gap formed through the one or more dielectric layers and the hardmask layer, the one or more dielectric layers comprising a low-k dielectric material at a first carbon content, and
a metal material disposed within the gap, the metal material comprising a first thickness and a first molybdenum oxide (MoOₓ) content;
flowing a process gas into the processing chamber; and
performing a redox operation on the semiconductor structure by applying a microwave energy to the process gas to form a processed semiconductor structure, the processed semiconductor structure comprising:
the low-k dielectric material at a second carbon content, and
the metal material comprising a second thickness and a second MoOₓ content, and
the process of applying the microwave energy to the process gas does not generate a plasma.

16. The method of claim 15, wherein the first carbon content is about 0.001% to about 1% greater than the second carbon content.

17. The method of claim 15, wherein the second thickness is about 60% to about 90% of the first thickness.

18. The method of claim 15, wherein the second MoOₓ content is about 80% to about 99.9% less than the first MoOₓ content.

19. The method of claim 15, wherein
the microwave energy is applied at a frequency greater than about 2.0 GHz and at a power of about 0.1 W to about 150 W, and
the process gas is selected from the group consisting of hydrogen (H₂), and water (H₂O).

20. The method of claim 19, wherein a pressure within the processing chamber during the redox operation is about 10 Torr to about 760 Torr.
